(19) United States
(12) Patent Application Publication
(10) Pub. No.: US 2026/0114202 A1
(43) Pub. Date: Apr. 23, 2026

(54) SEMICONDUCTOR SUBSTRATE AND STACKED STRUCTURE INCLUDING THE SAME

(71) Applicant: Samsung Electronics Co., Ltd., Suwon-si (KR)

(72) Inventors: GYEONG-SEON PARK, Suwon-si (KR); MINHWAN KIM, Suwon-si (KR); JONGUK SEO, Suwon-si (KR); JIHOON YUN, Suwon-si (KR); YONGSEOK CHOI, Suwon-si (KR); YOUNGCHEOL KIM, Suwon-si (KR); JONGSEOB KIM, Suwon-si (KR)

(21) Appl. No.: 19/199,004

(22) Filed: May 5, 2025

(30) Foreign Application Priority Data
Oct. 18, 2024 (KR) 10-2024-0143233

(51) Int. Cl. H01L 21/304; H01L 21/02

(52) U.S. Cl. CPC H10P 52/00; H10P 14/2904; H10P 90/128

(57) ABSTRACT

A method of manufacturing a semiconductor device includes providing a semiconductor substrate formed of silicon carbide. The semiconductor substrate has a first surface and a second surface opposite to each other in a first direction, and the semiconductor substrate has a ring-shaped edge region. The method further includes forming a die on the first surface, and performing a backside grinding process on the second surface to provide a backside surface at a virtual reference plane. The ring-shaped edge region includes a sidewall surface extending in the first direction and a first edge surface being between the first surface and the sidewall surface. A reference thickness between the first surface and the virtual reference plane in the first direction is 20 μm to 200 μm. A first edge height of the first edge surface in the first direction is smaller than the reference thickness.

### CROSS-REFERENCE TO RELATED APPLICATIONS

This U.S. non-provisional patent application claims priority under 35 U.S. C. § 119 of Korean Patent Application No. 10-2024-0143233, filed on Oct. 18, 2024, the entire contents of which are hereby incorporated by reference.

### BACKGROUND

The present disclosure herein relates to a semiconductor substrate including a bevel region and a stacked structure including the same. In addition, the present disclosure herein relates to a method of manufacturing a semiconductor device with the semiconductor substrate.

Silicon carbide (SiC), which is a crystal semiconductor material having a wide band gap characteristic, high hardness, high thermal conductivity, and chemically inert characteristic, may be used as a semiconductor substrate for manufacturing a power semiconductor element (or device). A power semiconductor element manufactured on an SiC substrate may have a higher power density and more improved performance than a power semiconductor element manufactured on a typical semiconductor substrate (e.g., silicon substrate).

Due to a shape of a bevel region of an SiC substrate, the SiC substrate may be broken during a substrate thinning process.

### SUMMARY

The present disclosure provides a semiconductor substrate that has a bevel region configured to enhance its strength making the substrate easy to handle and a stacked structure including the same.

The present disclosure also provides a semiconductor substrate having a bevel shape capable of preventing the substrate from being broken and a stacked structure including the same.

A method of manufacturing a semiconductor device according to the inventive concept may include providing a semiconductor substrate formed of silicon carbide. The semiconductor substrate has a first surface and a second surface opposite to each other in a first direction, and the semiconductor substrate has a ring-shaped edge region. The method of manufacturing a semiconductor device further including forming a die with the semiconductor substrate, including forming transistors on and/or within the first surface of the semiconductor substrate, and reducing the thickness of the semiconductor substrate by performing a backside grinding process on the second surface to remove the material of the semiconductor substrate to provide a backside surface at a virtual reference plane. The first direction may be perpendicular to the first surface and the second surface. The ring-shaped edge region may include a sidewall surface extending in the first direction and a first edge surface being between the first surface and the sidewall surface. The virtual reference plane is a plane between the first surface and the second plane and extends in a second direction parallel to the first surface and the second surface. A reference thickness between the first surface and the virtual reference plane in the first direction may be about 20 μm to about 200 μm. A first edge width of the first edge surface in the second direction may be equal to or smaller than the reference thickness, and a first edge height of the first edge surface in the first direction may be smaller than the reference thickness. The first edge surface is a first chamfered surface extending from the first surface to the sidewall surface.

A semiconductor substrate according to the inventive concept may have a first surface and a second surface opposite to each other in a first direction, and may include a ring-shaped edge region. The first direction may be perpendicular to the first surface and the second surface. The ring-shaped edge region may include a sidewall surface extending in the first direction, a first edge surface between the first surface and the sidewall surface, and a second edge surface between the second surface and the sidewall surface. The semiconductor substrate may have a first thickness that is a distance between the first surface and the second surface in the first direction. A first edge height of the first edge surface in the first direction is equal to or smaller than 65% of the first thickness of the semiconductor substrate.

A stacked structure according to the inventive concept may include: a semiconductor substrate having an upper surface and a lower surface opposite to each other in a first direction and including a ring-shaped edge region; and a plurality of semiconductor dies arranged on the upper surface of the semiconductor substrate. The first direction may be perpendicular to the upper surface and the lower surface of the semiconductor substrate. The ring-shaped edge region may include: a first edge surface adjacent to the upper surface of the semiconductor substrate; a second edge surface adjacent to the lower surface of the semiconductor substrate; and a sidewall surface extending in the first direction between the first edge surface and the second edge surface. The first edge surface may be a first chamfered surface extending from the upper surface of the semiconductor substrate to the sidewall surface, or may extend parallel to the upper surface of the semiconductor substrate and be perpendicular to the sidewall surface. The second edge surface may extend parallel to the lower surface of the semiconductor substrate and be perpendicular to the sidewall surface.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view of a semiconductor substrate according to some embodiments of the inventive concept;

FIGS. 2 to 12 are cross-sectional views, taken along line A-A′ of FIG. 1, illustrating a semiconductor substrate according to some embodiments of the inventive concept;

FIG. 13 is a plan view of a stacked structure according to some embodiments of the inventive concept;

FIG. 14 is a cross-sectional view taken along line B-B′ of FIG. 13; and

FIGS. 15 to 17 are enlarged views of the portion P1 of FIG. 14.

### DETAILED DESCRIPTION

Hereinafter, embodiments of the inventive concept will be described in detail with reference to the accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Terms such as “same,” “equal,” “flat,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

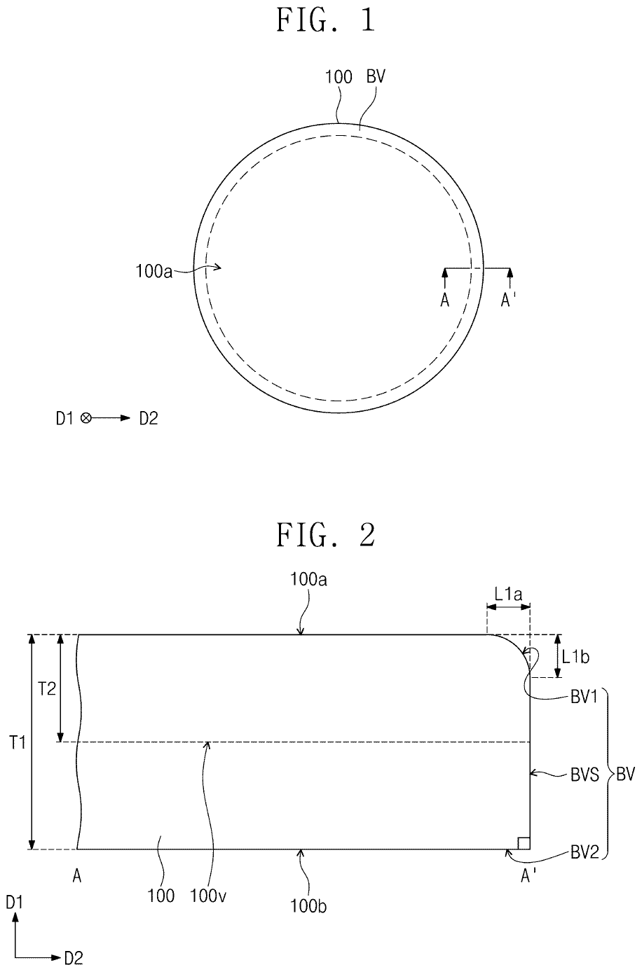

FIG. 1 is a plan view of a semiconductor substrate according to some embodiments of the inventive concept, and FIG. 2 is a cross-sectional view taken along line A-A′ of FIG. 1.

Referring to FIGS. 1 and 2, a semiconductor substrate 100 may have a first surface 100a and a second surface 100b opposite to each other in a first direction D1. The first direction D1 may be perpendicular to the first surface 100a and the second surface 100b. The semiconductor substrate 100 may be circular in a plan view and may be referred to as a wafer, for example. The first surface 100a may be an upper main surface of the semiconductor substrate 100, and may be a pattern surface on and/or in which one or more semiconductor dies (including integrated circuits and/or transistors) are to be formed. The second surface 100b may be a lower main surface of the semiconductor substrate 100, and may be a grinding surface on which a grinding process for manufacturing the semiconductor die is to be performed.

The semiconductor substrate 100 may include a bevel region (or an edge region) BV. The bevel region BV may have a ring shape in a plan view (top down view). The bevel region BV may be an edge region of the semiconductor substrate 100 and have a ring shape from a plan view. The bevel region BV may surround the regions in which the semiconductor dies are to be formed and may not be used to form semiconductor dies therein. The bevel region BV may include a first bevel region surface (or a first edge surface) BV1 adjacent to the first surface 100a, a second bevel region surface (or a second edge surface) BV2 adjacent to the second surface 100b, and a bevel region side surface (or a sidewall surface) BVS extending in the first direction D1 between the first bevel region surface BV1 and the second bevel region surface BV2. Each of the first edge surface BV1 and the second edge surface BV2 may have a ring shape in a plan view. The sidewall surface BVS may have a loop shape, extending around the perimeter of the semiconductor substrate 100. Not all surfaces in the bevel region (or the edge region) are necessarily chamfered, sloped, or curved, as is the case with the second bevel region surface BV2 and the bevel region side surface BVS.

The semiconductor substrate 100 may have a first thickness T1 in the first direction D1. The first thickness T1 may be a distance between the first surface 100a and the second surface 100b in the first direction D1. The first thickness T1 may be, for example, about 300 μm to about 550μm. A virtual reference surface (or a virtual reference plane) 100v, which is between the first surface 100a and the second surface 100b and extends in the second direction D2 parallel to the first surface 100a and the second surface 100b, may be defined. The reference surface 100v may correspond to a grinding stop surface of the grinding process performed on the second surface 100b of the semiconductor substrate 100. The semiconductor substrate 100 may have a second thickness T2 that is a distance between the first surface 100a and the reference surface 100v in the first direction D1. The second thickness T2 may be referred to as a reference thickness and may be about 20 μm to about 200 μm.

The semiconductor substrate 100 may include silicon carbide (SiC). The semiconductor substrate 100 may be a bulk silicon carbide substrate. For example, the semiconductor substrate 100 may be formed of silicon carbide having a cubic phase (e.g., 3C—SiC), a hexagonal phase (e.g., 4H—SiC, 6H—SiC). For example, the semiconductor substrate 100 may be formed of silicon carbide having a single crystalline phase or a polycrystalline phase. In some embodiments, the semiconductor substrate 100 may have material continuity. For example, the semiconductor substrate 100 may be a homogeneous monolithic structure, but the invention is not limited thereto. For example, the semiconductor substrate 100 may be a non-homogeneous structure. For example, the semiconductor substrate 100 may be a composite substrate including a silicon carbide layer formed on an insulating layer. A diameter of the semiconductor substrate 100 may be, for example, about 4 inches, about 6 inches, or about 8 inches, but the inventive concept is not limited thereto.

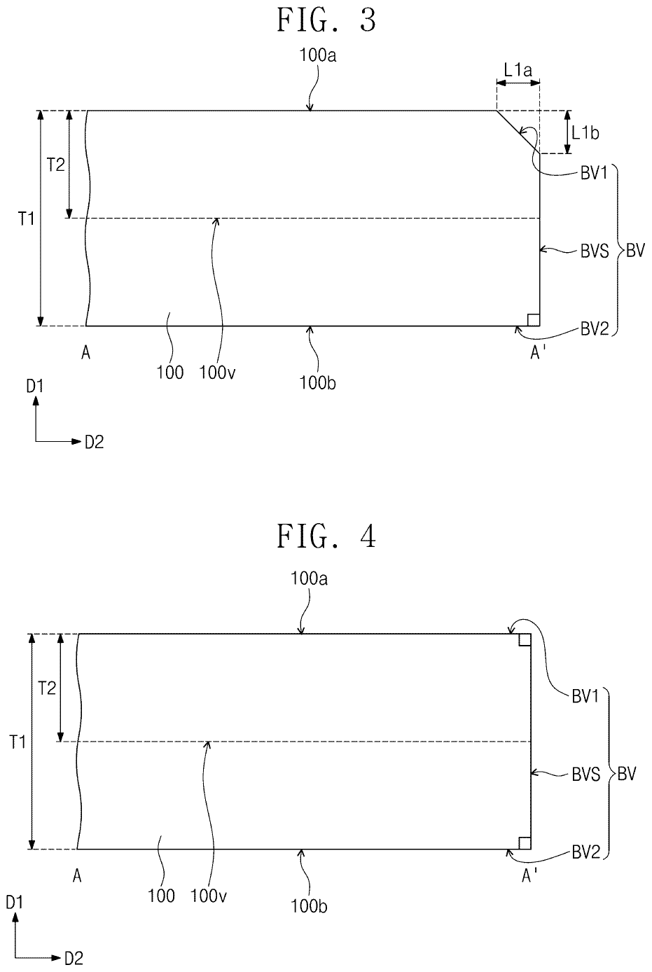

According to some embodiments, the first bevel region surface BV1 and the second bevel region surface BV2 may be asymmetric with respect to the reference surface 100v in the first direction D1. For example, the first bevel region surface BV1 and the second surface BV2 may be asymmetrical with respect to the reference surface 100v, in such a way that they are asymmetrical relative to each other with respect to the reference surface 100v. The first bevel region surface BV1 may be a chamfered surface. For example, the chamfered surface BV1 may be formed by removing (or deburring) a sharp edge portion of the substrate 100. The first bevel region surface BV1 may be inclined with respect to the first surface 100a, and may extend from the first surface 100a to the bevel region side surface (sidewall surface) BVS. The first bevel region surface BV1 may be a curved surface that is convex toward the outside of the semiconductor substrate 100 between the first surface 100a and the bevel region side surface BVS. In some embodiments, the chamfered surface may be a flat surface as described later in FIGS. 3, 6, 9 and 12.

The first bevel region surface BV1 may have a first bevel width (or a first edge width) L1a in the second direction D2 and a first bevel height (or a first edge height) L1b in the first direction D1. The first bevel width L1a may be equal to or smaller than the second thickness T2 of the semiconductor substrate 100, and may be larger than about 0 μm and equal to or smaller than about 200 μm. The first bevel height L1b may be smaller than the second thickness T2 of the semiconductor substrate 100, and may be larger than about 0 μm and smaller than about 200 μm. The first bevel height L1b and the first bevel width L1a may each be equal to or smaller than about 65% of the first thickness T1 of the semiconductor substrate 100.

The second bevel region surface BV2 may be parallel to the second surface 100b and perpendicular to the bevel region side surface BVS. The second bevel region surface (second edge surface) BV2 may extend from the second surface 100b in the second direction D2. In some embodiments, the second edge surface BV2 may be a chamfered surface as described later in FIGS. 5 to 12.

When the bevel region BV of the semiconductor substrate 100 is processed so as to have a pointed shape toward the outside of the semiconductor substrate 100 through the grinding process, the bevel region BV having the pointed shape may be vulnerable to an external impact, and, as a result, the semiconductor substrate 100 may be easily broken.

According to some embodiments of the inventive concept, the first bevel region surface BV1 may be formed so as to have the first bevel width L1a that is equal to or smaller than the second thickness T2 of the semiconductor substrate 100 and have the first bevel height L1b that is smaller than the second thickness T2 of the semiconductor substrate 100. In addition, the second bevel region surface BV2 may be formed so as to be perpendicular to the bevel region side surface BVS. In this case, even after the grinding process is performed so that the semiconductor substrate 100 has the second thickness T2, the bevel region BV of the semiconductor substrate 100 may include at least a portion of the bevel region side surface BVS extending in the first direction D1, and, accordingly, the bevel region BV may not have a pointed shape toward the outside of the semiconductor substrate 100. For example, even after the grinding process, the bevel region BV of the semiconductor substrate 100 may include at least a portion of the bevel region side surface BVS extending in the first direction D1, and thus the bevel region BV of the semiconductor substrate 100 may have increased strength against an external impact. As a result, the semiconductor substrate 100 may be prevented from being broken.

FIG. 3 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 3, according to some embodiments, the first bevel region surface BV1 and the second bevel region surface BV2 may be asymmetric with respect to the reference surface 100v in the first direction D1. For example, the first bevel region surface BV1 and the second bevel region surface BV2 may be asymmetrical with respect to the reference surface 100v, in such a way that they are asymmetrical relative to each other with respect to the reference surface 100v. The first bevel region surface BV1 may be inclined from the first surface 100a to the bevel region side surface BVS. The first bevel region surface BV1 may be an inclined plane between the first surface 100a and the bevel region side surface BVS. The second bevel region surface BV2 may be parallel to the second surface 100b and perpendicular to the bevel region side surface BVS. The first bevel region surface BV1 may be a chamfered surface. For example, the chamfered surface BV1 may be formed by removing (or deburring) a sharp edge portion of the substrate 100. The first bevel region surface BV1 may be inclined with respect to the first surface 100a, and may extend from the first surface 100a to the bevel region side surface (sidewall surface) BVS. The chamfered surface BV1 may be a flat surface. The semiconductor substrate 100 according to the present embodiments is substantially the same as the semiconductor substrate 100 described with reference to FIGS. 1 and 2 except for the above-mentioned differences.

FIG. 4 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 4, according to some embodiments, the first bevel region surface (or the first edge surface) BV1 and the second bevel region surface (or the second edge surface) BV2 may be symmetric with respect to the reference surface 100v in the first direction D1. The first edge surface BV1 may be parallel to the first surface 100a and perpendicular to the bevel region side surface (or the sidewall surface) BVS. The second edge surface BV2 may be parallel to the second surface 100b and perpendicular to the bevel region side surface (or the sidewall surface) BVS. The first edge surface BV1 may extend from the first surface 100a in the second direction D2. The second edge surface BV2 may extend from the second surface 100b in the second direction D2.

According to some embodiments of the inventive concept, the first edge surface BV1 and the second edge surface BV2 may be formed so as to be perpendicular to the bevel region side surface (or the sidewall surface) BVS. In this case, even after the grinding process is performed so that the semiconductor substrate 100 has the second thickness T2, the bevel region (or the edge region) BV of the semiconductor substrate 100 may include at least a portion of the bevel region side surface (or the sidewall surface) BVS extending in the first direction D1, and thus the bevel region (or the edge region) BV of the semiconductor substrate 100 may have increased strength against an external impact. As a result, the semiconductor substrate 100 may be prevented from being broken.

FIG. 5 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 5, according to some embodiments, the first bevel region surface BV1 and the second bevel region surface BV2 may be asymmetric with respect to the reference surface 100v in the first direction D1. For example, the first bevel region surface BV1 and the second bevel region surface BV2 may be asymmetrical with respect to the reference surface 100v, in such a way that they are asymmetrical relative to each other with respect to the reference surface 100v.

The first bevel region surface BV1 may be inclined from the first surface 100a to the bevel region side surface BVS. The first bevel region surface BV1 may be a curved surface that is convex toward the outside of the semiconductor substrate 100 between the first surface 100a and the bevel region side surface BVS. The first bevel region surface BV1 may have a first bevel width (or a first edge width) L1a in the second direction D2 and a first bevel height (or a first edge height) L1b in the first direction D1. The first bevel width L1a may be equal to or smaller than the second thickness T2 of the semiconductor substrate 100, and may be larger than about 0 μm and equal to or smaller than about 200 μm. The first bevel height L1b may be smaller than the second thickness T2 of the semiconductor substrate 100, and may be larger than about 0 μm and smaller than about 200 μm. The first bevel height L1b and the first bevel width L1a may each be equal to or smaller than about 65 % of the first thickness T1 of the semiconductor substrate 100.

The second bevel region surface BV2 may be inclined from the second surface 100b to the bevel region side surface BVS. The second bevel region surface BV2 may be a curved surface that is convex toward the outside of the semiconductor substrate 100 between the second surface 100b and the bevel region side surface BVS. The second bevel region surface BV2 may have a second bevel width (or a second edge width) L2a in the second direction D2 and a second bevel height (or a second edge height) L2b in the first direction D1. The second bevel width L2a may be larger than the first bevel width L1a, and the second bevel height L2b may be larger than the first bevel height L1b. The second bevel region surface BV2 may be a chamfered surface. For example, the chamfered surface BV2 may be formed by removing (or deburring) a sharp edge portion of the substrate 100. The second bevel region surface BV2 may be inclined with respect to the second surface 100b, and may extend from the second surface 100b to the bevel region side surface (sidewall surface) BVS.

According to some embodiments of the inventive concept, the first bevel region surface BV1 may be formed so as to have the first bevel width L1a that is equal to or smaller than the second thickness T2 of the semiconductor substrate 100 and have the first bevel height L1b that is smaller than the second thickness T2 of the semiconductor substrate 100. In this case, even after the grinding process is performed so that the semiconductor substrate 100 has the second thickness T2, the bevel region BV of the semiconductor substrate 100 may include at least a portion of the bevel region side surface BVS extending in the first direction D1, and thus the bevel region BV of the semiconductor substrate 100 may have increased strength against an external impact. As a result, the semiconductor substrate 100 may be prevented from being broken.

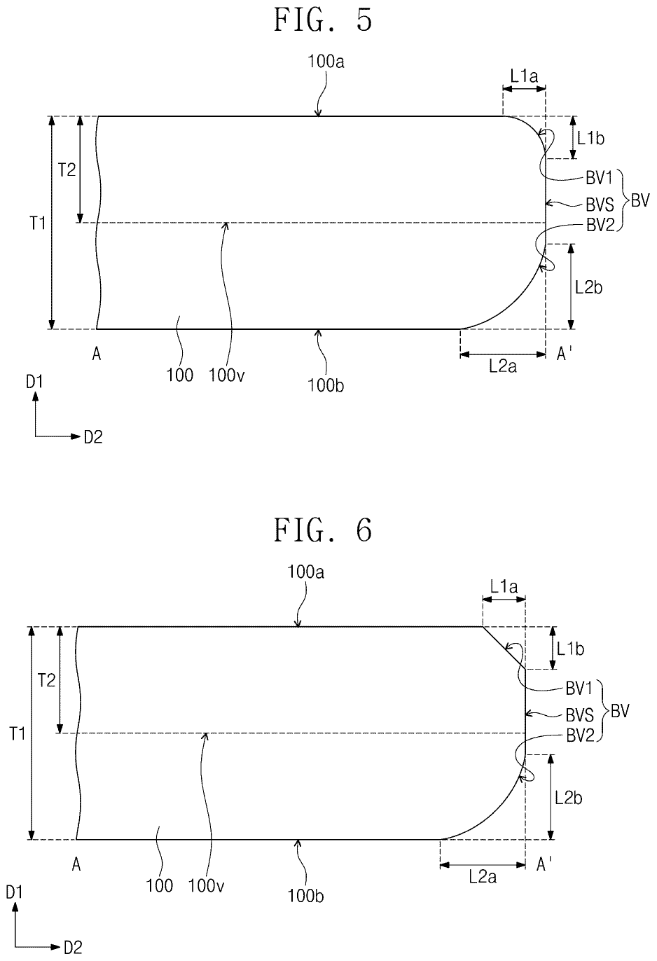

FIG. 6 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 6, according to some embodiments, the first bevel region surface BV1 and the second bevel region surface BV2 may be asymmetric with respect to the reference surface 100v in the first direction D1. For example, the first bevel region surface BV1 and the second bevel region surface BV2 may be asymmetrical with respect to the reference surface 100v, in such a way that they are asymmetrical relative to each other with respect to the reference surface 100v. The first bevel region surface BV1 may be inclined from the first surface 100a to the bevel region side surface BVS. The first bevel region surface BV1 may be an inclined plane between the first surface 100a and the bevel region side surface BVS. The second bevel region surface BV2 may be inclined from the second surface 100b to the bevel region side surface BVS. The second bevel region surface BV2 may be a curved surface that is convex toward the outside of the semiconductor substrate 100 between the second surface 100b and the bevel region side surface BVS. The semiconductor substrate 100 according to the present embodiments is substantially the same as the semiconductor substrate 100 described with reference to FIGS. 1 and 5 except for the above-mentioned differences. The second bevel region surface BV2 may be a chamfered surface. For example, the chamfered surface BV2 may be formed by removing (or deburring) a sharp edge portion of the substrate 100. The second bevel region surface BV2 may be inclined with respect to the second surface 100b, and may extend from the second surface 100b to the bevel region side surface (sidewall surface) BVS.

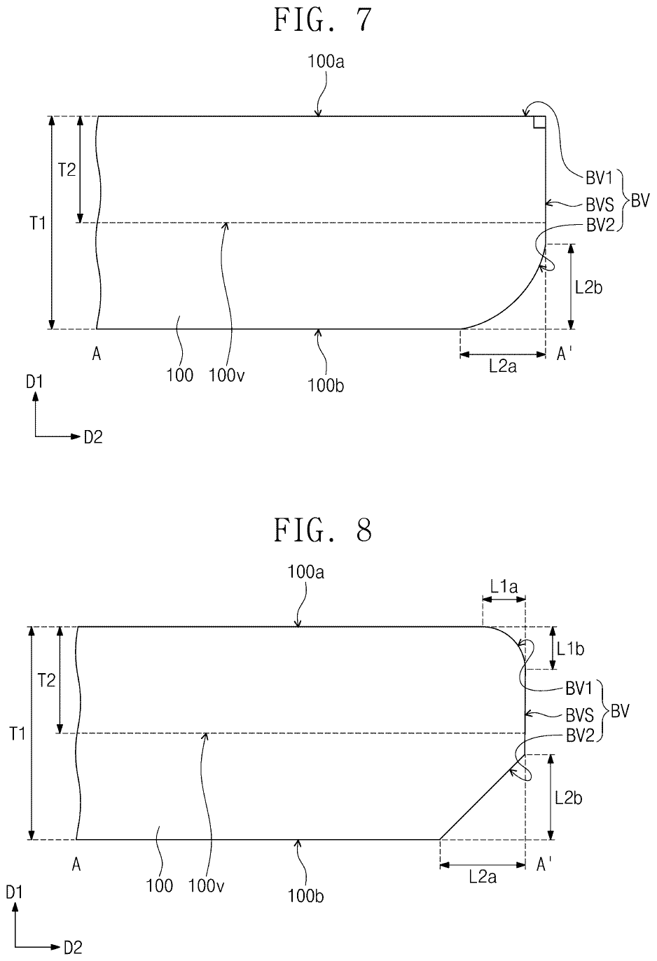

FIG. 7 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 7, according to some embodiments, the first bevel region surface BV1 and the second bevel region surface BV2 may be asymmetric with respect to the reference surface 100v in the first direction D1. For example, the first bevel region surface BV1 and the second bevel region surface BV2 may be asymmetrical with respect to the reference surface 100v, in such a way that they are asymmetrical relative to each other with respect to the reference surface 100v. The first bevel region surface BV1 may be parallel to the first surface 100a and perpendicular to the bevel region side surface BVS. The second bevel region surface BV2 may be inclined from the second surface 100b to the bevel region side surface BVS. The second bevel region surface BV2 may be a curved surface that is convex toward the outside of the semiconductor substrate 100 between the second surface 100b and the bevel region side surface BVS. The second bevel region surface BV2 may be a chamfered surface. For example, the chamfered surface BV2 may be formed by removing (or deburring) a sharp edge portion of the substrate 100. The second bevel region surface BV2 may be inclined with respect to the second surface 100b, and may extend from the second surface 100b to the bevel region side surface (sidewall surface) BVS.

According to some embodiments of the inventive concept, the first bevel region surface BV1 may be formed so as to be perpendicular to the bevel region side surface BVS. In this case, even after the grinding process is performed so that the semiconductor substrate 100 has the second thickness T2, the bevel region BV of the semiconductor substrate 100 may include at least a portion of the bevel region side surface BVS extending in the first direction D1, and thus the bevel region BV of the semiconductor substrate 100 may have increased strength against an external impact. As a result, the semiconductor substrate 100 may be prevented from being broken.

FIG. 8 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 8, according to some embodiments, the first bevel region surface BV1 and the second bevel region surface BV2 may be asymmetric with respect to the reference surface 100v in the first direction D1. For example, the first bevel region surface BV1 and the second bevel region surface BV2 may be asymmetrical with respect to the reference surface 100v, in such a way that they are asymmetrical relative to each other with respect to the reference surface 100v.

The first bevel region surface BV1 may be inclined from the first surface 100a to the bevel region side surface BVS. The first bevel region surface BV1 may be a curved surface that is convex toward the outside of the semiconductor substrate 100 between the first surface 100a and the bevel region side surface BVS. The first bevel region surface BV1 may have a first bevel width (or a first edge width) L1a in the second direction D2 and a first bevel height (or a first edge height) L1b in the first direction D1. The first bevel width L1a may be equal to or smaller than the second thickness T2 of the semiconductor substrate 100, and may be larger than about 0 μm and equal to or smaller than about 200 μm. The first bevel height L1b may be smaller than the second thickness T2 of the semiconductor substrate 100, and may be larger than about 0 μm and smaller than about 200 μm. The first bevel height L1b and the first bevel width L1a may each be equal to or smaller than about 65 % of the first thickness T1 of the semiconductor substrate 100.

The second bevel region surface BV2 may be inclined from the second surface 100b to the bevel region side surface BVS. The second bevel region surface BV2 may be an inclined plane between the second surface 100b and the bevel region side surface BVS. The second bevel region surface BV2 may have a second bevel width (or a second edge width) L2a in the second direction D2 and a second bevel height (or a second edge height) L2b in the first direction D1. The second bevel width L2a may be larger than the first bevel width L1a, and the second bevel height L2b may be larger than the first bevel height L1b. The second bevel region surface BV2 may be a chamfered surface. For example, the chamfered surface BV2 may be formed by removing (or deburring) a sharp edge portion of the substrate 100. The second bevel region surface BV2 may be inclined with respect to the second surface 100b, and may extend from the second surface 100b to the bevel region side surface (sidewall surface) BVS.

According to some embodiments of the inventive concept, the first bevel region surface BV1 may be formed so as to have the first bevel width L1a that is equal to or smaller than the second thickness T2 of the semiconductor substrate 100 and have the first bevel height L1b that is smaller than the second thickness T2 of the semiconductor substrate 100. In this case, even after the grinding process is performed so that the semiconductor substrate 100 has the second thickness T2, the bevel region BV of the semiconductor substrate 100 may include at least a portion of the bevel region side surface BVS extending in the first direction D1, and thus the bevel region BV of the semiconductor substrate 100 may have increased strength against an external impact. As a result, the semiconductor substrate 100 may be prevented from being broken.

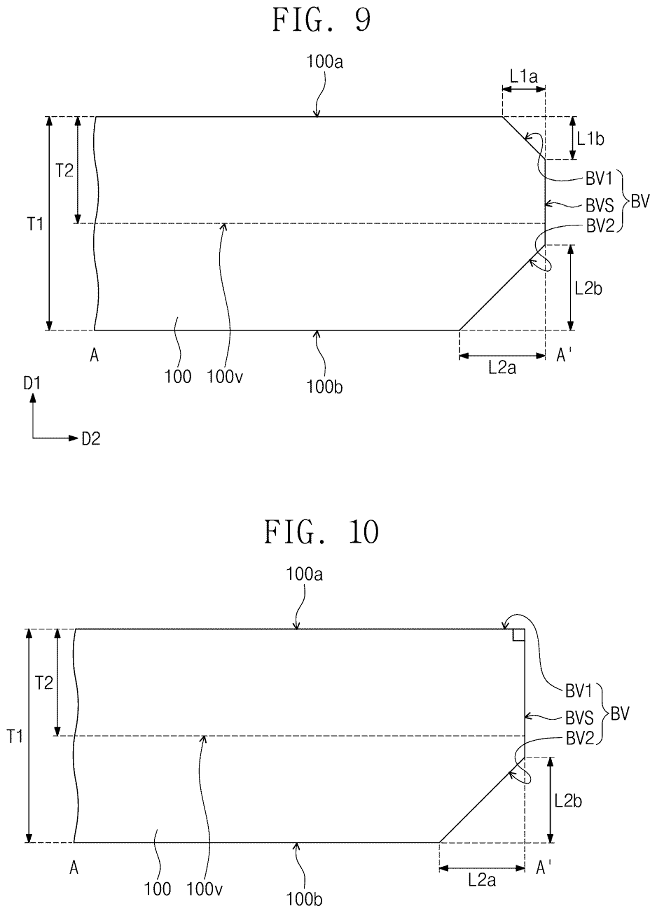

FIG. 9 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 9, according to some embodiments, the first bevel region surface BV1 and the second bevel region surface BV2 may be asymmetric with respect to the reference surface 100v in the first direction D1. For example, the first bevel region surface BV1 and the second bevel region surface BV2 may be asymmetrical with respect to the reference surface 100v, in such a way that they are asymmetrical relative to each other with respect to the reference surface 100v. The first bevel region surface BV1 may be inclined from the first surface 100a to the bevel region side surface BVS. The first bevel region surface BV1 may be an inclined plane between the first surface 100a and the bevel region side surface BVS. The second bevel region surface BV2 may be inclined from the second surface 100b to the bevel region side surface BVS. The second bevel region surface BV2 may be an inclined plane between the second surface 100b and the bevel region side surface BVS. The semiconductor substrate 100 according to the present embodiments is substantially the same as the semiconductor substrate 100 described with reference to FIGS. 1 and 8 except for the above-mentioned differences.

FIG. 10 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 10, according to some embodiments, the first bevel region surface BV1 and the second bevel region surface BV2 may be asymmetric with respect to the reference surface 100v in the first direction D1. For example, the first bevel region surface BV1 and the second bevel region surface BV2 may be asymmetrical with respect to the reference surface 100v, in such a way that they are asymmetrical relative to each other with respect to the reference surface 100v. The first bevel region surface BV1 may be parallel to the first surface 100a and perpendicular to the bevel region side surface BVS. The second bevel region surface BV2 may be inclined from the second surface 100b to the bevel region side surface BVS. The second bevel region surface BV2 may be an inclined plane between the second surface 100b and the bevel region side surface BVS. The second bevel region surface BV2 may be a chamfered surface. For example, the chamfered surface BV2 may be formed by removing (or deburring) a sharp edge portion of the substrate 100. The second bevel region surface BV2 may be inclined with respect to the second surface 100b, and may extend from the second surface 100b to the bevel region side surface (sidewall surface) BVS.

According to some embodiments of the inventive concept, the first bevel region surface BV1 may be formed so as to be perpendicular to the bevel region side surface BVS. In this case, even after the grinding process is performed so that the semiconductor substrate 100 has the second thickness T2, the bevel region BV of the semiconductor substrate 100 may include at least a portion of the bevel region side surface BVS extending in the first direction D1, and thus the bevel region BV of the semiconductor substrate 100 may have increased strength against an external impact. As a result, the semiconductor substrate 100 may be prevented from being broken.

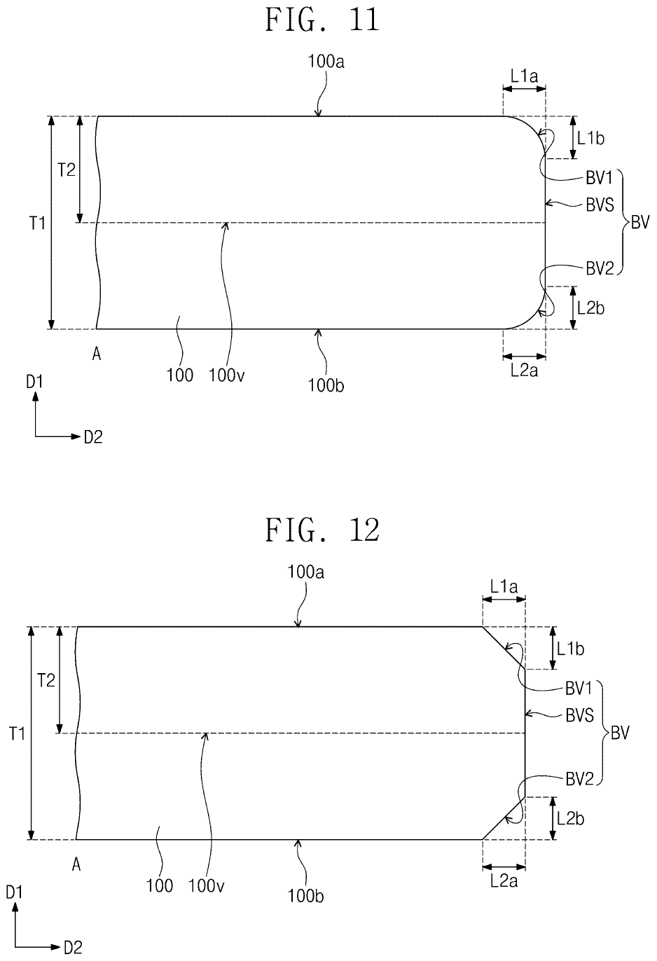

FIG. 11 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 11, according to some embodiments, the first bevel region surface BV1 and the second bevel region surface BV2 may be symmetric with respect to the reference surface 100v.

The first bevel region surface BV1 may be inclined from the first surface 100a to the bevel region side surface BVS. The first bevel region surface BV1 may be a curved surface that is convex toward the outside of the semiconductor substrate 100 between the first surface 100a and the bevel region side surface BVS. The first bevel region surface BV1 may have a first bevel width L1a in the second direction D2 and a first bevel height L1b in the first direction D1. The first bevel width L1a may be equal to or smaller than the second thickness T2 of the semiconductor substrate 100, and may be larger than about 0 μm and equal to or smaller than about 200 μm. The first bevel height L1b may be smaller than the second thickness T2 of the semiconductor substrate 100, and may be larger than about 0 μm and smaller than about 200 μm. The first bevel height L1b and the first bevel width L1a may each be equal to or smaller than about 65 % of the first thickness T1 of the semiconductor substrate 100.

The second bevel region surface BV2 may be inclined from the second surface 100b to the bevel region side surface BVS. The second bevel region surface BV2 may be a curved surface that is convex toward the outside of the semiconductor substrate 100 between the second surface 100b and the bevel region side surface BVS. The second bevel region surface BV2 may have a second bevel width L2a in the second direction D2 and a second bevel height L2b in the first direction D1. The second bevel width L2a may be equal to the first bevel width L1a, and the second bevel height L2b may be equal to the first bevel height L1b. The second bevel region surface BV2 may be a chamfered surface. For example, the chamfered surface BV2 may be formed by removing (or deburring) a sharp edge portion of the substrate 100. The second bevel region surface BV2 may be inclined with respect to the second surface 100b, and may extend from the second surface 100b to the bevel region side surface (sidewall surface) BVS.

According to some embodiments of the inventive concept, the first bevel region surface BV1 may be formed so as to have the first bevel width L1a that is equal to or smaller than the second thickness T2 of the semiconductor substrate 100 and have the first bevel height L1b that is smaller than the second thickness T2 of the semiconductor substrate 100. In addition, the second bevel region surface BV2 may be formed so as to have the second bevel width L2a that is equal to the first bevel width L1a and have the second bevel height L2b that is equal to the first bevel height L1b. In this case, even after the grinding process is performed so that the semiconductor substrate 100 has the second thickness T2, the bevel region BV of the semiconductor substrate 100 may include at least a portion of the bevel region side surface BVS extending in the first direction D1, and thus the bevel region BV of the semiconductor substrate 100 may have increased strength against an external impact. As a result, the semiconductor substrate 100 may be prevented from being broken.

FIG. 12 is a cross-sectional view of a semiconductor substrate, taken along line A-A′ of FIG. 1, according to some embodiments of the inventive concept. For conciseness, differences from the semiconductor substrate described with reference to FIGS. 1 and 2 will be mainly described.

Referring to FIGS. 1 and 12, according to some embodiments, the first bevel region surface BV1 and the second bevel region surface BV2 may be symmetric with respect to the reference surface 100v. The first bevel region surface BV1 may be inclined from the first surface 100a to the bevel region side surface BVS. The first bevel region surface BV1 may be an inclined plane between the first surface 100a and the bevel region side surface BVS. The second bevel region surface BV2 may be inclined from the second surface 100b to the bevel region side surface BVS. The second bevel region surface BV2 may be an inclined plane between the second surface 100b and the bevel region side surface BVS. The semiconductor substrate 100 according to the present embodiments is substantially the same as the semiconductor substrate 100 described with reference to FIGS. 1 and 11 except for the above-mentioned differences. The first bevel region surface BV1 and the second bevel region surface BV2 may be flat surfaces.

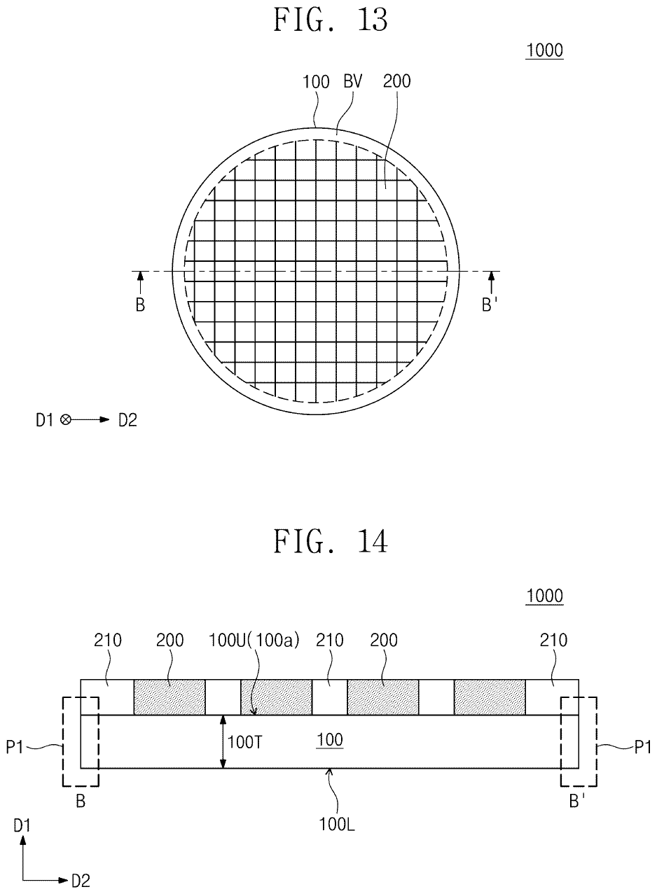

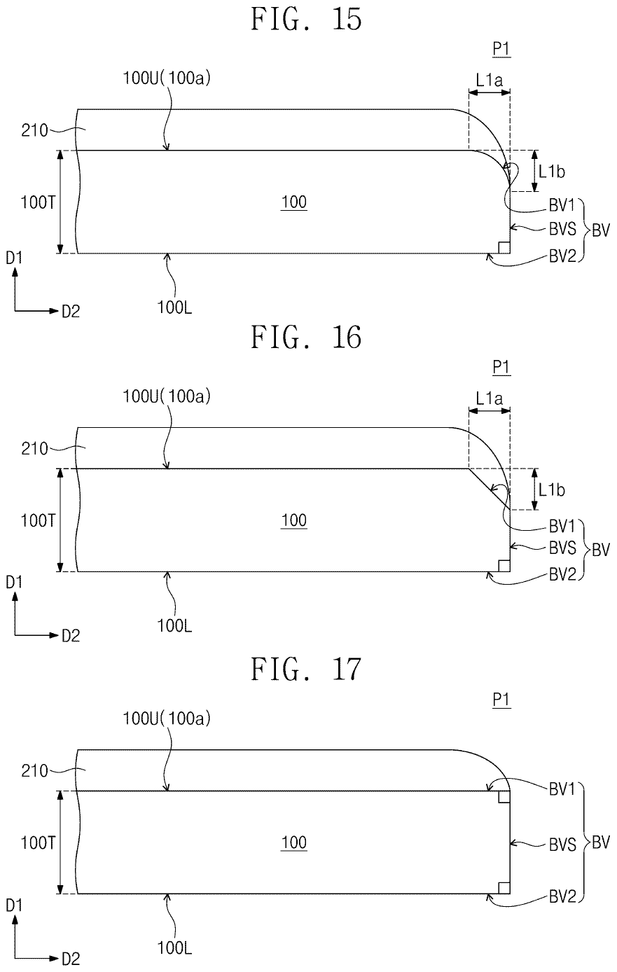

FIG. 13 is a plan view of a stacked structure according to some embodiments of the inventive concept, and FIG. 14 is a cross-sectional view taken along line B-B′ of FIG. 13. FIGS. 15 to 17 are enlarged views of the portion P1 of FIG. 14.

Referring to FIGS. 13 and 14, a stacked structure 1000 may include the semiconductor substrate 100, semiconductor dies 200 on the semiconductor substrate 100, and an insulating layer 210 disposed on the semiconductor substrate 100 and filling a space between the semiconductor dies 200. The semiconductor substrate 100 may have an upper surface 100U and a lower surface 100L opposite to each other in the first direction D1. The first direction D1 may be perpendicular to the upper surface 100U and the lower surface 100L of the semiconductor substrate 100. The upper surface 100U of the semiconductor substrate 100 may correspond to the first surface 100a of the semiconductor substrate 100 described above with reference to FIGS. 1 to 12. The semiconductor dies 200 and the insulating layer 210 may be arranged on the upper surface 100U of the semiconductor substrate 100. The semiconductor dies 200 may each include an integrated circuit (and/or a transistor), and the insulating layer 210 may include an insulating material.

In some embodiments, each of the semiconductor dies 200 may be electrically connected to a portion of the substrate 100. For example, each of the semiconductor dies 200 may include an impurity-doped region. For example, the impurity-doped region may include charge carrier dopants introduced by, e.g., an ion implantation process. The substrate 100 and the impurity-doped region may have material continuity. Each of the semiconductor dies 200 and the impurity-doped region may constitute a power semiconductor device (e.g., a metal oxide semiconductor field effect transistor (MOSFET), a super junction MOSFET, a double trench MOSFET, an insulated gate bipolar transistor (IGBT)). Accordingly, the semiconductor die 200 may be a part of the semiconductor device, and a portion of the substrate 100 may include a part of the semiconductor device.

The semiconductor substrate 100 may be circular in a plan view and may be referred to as a wafer, for example. The semiconductor substrate 100 may include a bevel region BV. The bevel region BV may be an edge region of the semiconductor substrate 100, in which the semiconductor dies 200 are not formed. The bevel region BV (or ring-shaped edge region) may have a ring shape in a plan view.

The semiconductor substrate 100 may have a thickness 100T in the first direction D1. The thickness 100T of the semiconductor substrate 100 may be a distance between the upper surface 100U and the lower surface 100L in the first direction D1. The thickness 100T of the semiconductor substrate 100 may correspond to the second thickness T2 (i.e., the reference thickness) of the semiconductor substrate 100 described above with reference to FIGS. 1 to 12. The thickness 100T of the semiconductor substrate 100 may be about 20 μm to about 200 μm.

The semiconductor substrate 100 may include silicon carbide (SiC). The semiconductor substrate 100 may be a bulk silicon carbide substrate. For example, the semiconductor substrate 100 may be formed of silicon carbide having a cubic phase (e.g., 3C—SiC), a hexagonal phase (e.g., 4H—SiC, 6H—SiC). For example, the semiconductor substrate 100 may be formed of silicon carbide having a single crystalline phase or a polycrystalline phase. In some embodiments, the semiconductor substrate 100 may have material continuity. For example, the semiconductor substrate 100 may be a homogeneous monolithic structure, but the inventive concept is not limited thereto. For example, the semiconductor substrate 100 may be a non-homogeneous structure, such as being formed of different material layers. The semiconductor substrate 100 may include multiple material layers, forming a non-homogeneous configuration. A diameter of the semiconductor substrate 100 may be, for example, about 4 inches, about 6 inches, or about 8 inches, but the inventive concept is not limited thereto.

Referring to FIGS. 15 to 17, the bevel region (or the edge region) BV may include a first bevel region surface (or a first edge surface) BV1 adjacent to the upper surface 100U of the semiconductor substrate 100, a second bevel region surface (or a second edge surface) BV2 adjacent to the lower surface 100L of the semiconductor substrate 100, and a bevel region side surface (a sidewall surface) BVS extending in the first direction D1 between the first bevel region surface BV1 and the second bevel region surface BV2. According to some embodiments, the insulating layer 210 may extend from the upper surface 100U of the semiconductor substrate 100 onto the first bevel region surface BV1 and cover at least a portion of the first bevel region surface BV1. According to other embodiments, the first bevel region surface BV1 may be exposed to the outside without being covered with the insulating layer 210.

According to some embodiments, the first bevel region surface BV1 may be inclined from the upper surface 100U to the bevel region side surface BVS as illustrated in FIG. 15. The first bevel region surface BV1 may be a curved surface that is convex toward the outside of the semiconductor substrate 100 between the upper surface 100U and the bevel region side surface BVS. The first bevel region surface BV1 may have a first bevel width L1a in the second direction D2 and a first bevel height L1b in the first direction D1. The second direction D2 may be parallel to the upper surface 100U and the lower surface 100L of the semiconductor substrate 100. The first bevel width L1a may be equal to or smaller than the thickness 100T of the semiconductor substrate 100, and may be larger than about 0 μm and equal to or smaller than about 200 μm. The first bevel height L1b may be smaller than the thickness 100T of the semiconductor substrate 100, and may be larger than about 0 μm and smaller than about 200 μm. The second bevel region surface BV2 may be parallel to the lower surface 100L and perpendicular to the bevel region side surface BVS.

According to other embodiments, the first bevel region surface BV1 may be inclined from the upper surface 100U to the bevel region side surface BVS as illustrated in FIG. 16. The first bevel region surface BV1 may be an inclined plane between the upper surface 100U and the bevel region side surface BVS. The first bevel region surface BV1 may have the first bevel width L1a and the first bevel height L1b. The second bevel region surface BV2 may be parallel to the lower surface 100L and perpendicular to the bevel region side surface BVS.

In some embodiments, as described in FIGS. 15 and 16, the first bevel region surface BV1 may be a chamfered surface. For example, the chamfered surface BV1 may be formed by removing (or deburring) a sharp edge portion of the substrate 100. For example, the chamfered surface may be a flat surface as described in FIG. 16, or may be a curved surface as described in FIG. 15.

Furthermore, according to other embodiments, the first bevel region surface (or the first edge surface) BV1 may be parallel to the upper surface 100U and perpendicular to the bevel region side surface (or the sidewall surface) BVS as illustrated in FIG. 17. The second bevel region surface (or the second edge surface) BV2 may be parallel to the lower surface 100L and perpendicular to the bevel region side surface (or the sidewall surface) BVS. The first bevel region surface(or the first edge surface) BV1 may extend from the upper surface 100U in the second direction D2. The second bevel region surface (or the second edge surface) BV2 may extend from the lower surface 100L in the second direction D2.

According to an embodiment, a method for manufacturing a semiconductor device is provided. It will be apparent to those skilled in the art that various modifications of the present invention are possible, including a method for manufacturing a semiconductor device using the semiconductor substrates and grinding process described above, without departing from the spirit or scope of the invention.

Referring to the drawings discussed above, a semiconductor substrate 100 may include a bevel region (or an edge region) BV. The bevel region BV may have a ring shape in a plan view (top down view). The bevel region BV may be an edge region of the semiconductor substrate 100 and have a ring shape from a plan view. The bevel region BV may surround the regions in which the semiconductor dies are to be formed and may not be used to form semiconductor dies therein.

For example, A method of manufacturing a semiconductor device may include providing a semiconductor substrate 100. The semiconductor substrate 100 may be any of the semiconductor substrates from the embodiments described above. The semiconductor substrate 100 may be formed of silicon carbide. The semiconductor substrate 100 may have a first surface 100a and a second surface 100b opposite to each other in the first direction D1. The first surface 100a and second surface 100b may be major surfaces of the semiconductor substrate 100. The semiconductor substrate 100 may have a ring-shaped edge region. A plurality of dies including integrated circuits and/or transistors may be formed on and/or within the first surface 100a of the semiconductor substrate 100.

In some embodiments, one or more patterned conductive layers may be formed on the semiconductor substrate 100. Insulating layers may be formed between the patterned conductive layers. Conductive vias may be formed between pattern elements of the conductive layers to interconnect the transistors, e.g., to form logic gates of the integrated circuit.

The thickness T1 of the semiconductor substrate 100 may be reduced by performing a backside grinding process on the second surface 100b to remove the material of the semiconductor substrate and to provide a backside surface at the virtual reference plane 100v. The semiconductor substrate 100 may be cut in to a plurality of individual semiconductor dies. In an example, each of the plurality of individual semiconductor dies may have a corresponding portion of the backside surface positioned at the virtual reference plane 100v.

According to embodiments of the inventive concept, even after the grinding process is performed on the lower surface 100L of the semiconductor substrate 100 so that the semiconductor substrate 100 has the thickness 100T, the bevel region BV of the semiconductor substrate 100 may include at least a portion of the bevel region side surface BVS extending in the first direction D1, and, accordingly, the bevel region BV may not have a pointed shape toward the outside of the semiconductor substrate 100. That is, even after the grinding process, the bevel region BV of the semiconductor substrate 100 may include at least a portion of the bevel region side surface BVS extending in the first direction D1, and thus the bevel region BV of the semiconductor substrate 100 may have increased strength against an external impact. Therefore, the semiconductor substrate 100 may be prevented from being broken, and the semiconductor substrate 100 and the stacked structure 1000 may be easily handled.

According to the inventive concept, even after a grinding process is performed on a lower surface of a semiconductor substrate, a bevel region of the semiconductor substrate may include at least a portion of a bevel region side surface extending in a direction perpendicular to an upper surface of the semiconductor substrate. Accordingly, the bevel region of the semiconductor substrate may have increased strength against an external impact. Therefore, the semiconductor substrate may be prevented from being broken, and the semiconductor substrate and the stacked structure may be easily handled.

The above descriptions of embodiments of the inventive concept provide examples for describing the inventive concept. Therefore, the inventive concept is not limited to the above embodiments, and it would be obvious that those skilled in the art could make various modifications and changes (e.g., by combining the above embodiments) within the technical spirit of the inventive concept.

What is claimed is:

1. A method of manufacturing a semiconductor device, comprising:
providing a semiconductor substrate formed of silicon carbide, the semiconductor substrate having a first surface and a second surface opposite to each other in a first direction and having a ring-shaped edge region;
forming a die with the semiconductor substrate, including forming a transistor on and/or within the first surface of the semiconductor substrate; and
reducing a thickness of the semiconductor substrate by performing a backside grinding process on the second surface to remove a material of the semiconductor substrate to provide a backside surface at a virtual reference plane,
wherein:
the first direction is perpendicular to the first surface and the second surface,
the ring-shaped edge region includes:
a sidewall surface extending in the first direction, and
a first edge surface being between the first surface and the sidewall surface,
the virtual reference plane is a plane between the first surface and the second surface and extends in a second direction parallel to the first surface and the second surface, and a reference thickness between the first surface and the virtual reference plane in the first direction is 20 μm to 200 μm,
a first edge width of the first edge surface in the second direction is equal to or smaller than the reference thickness,
a first edge height of the first edge surface in the first direction is smaller than the reference thickness, and
the first edge surface is a first chamfered surface extending from the first surface to the sidewall surface.

2. The method of claim 1, wherein the first edge surface is a curved surface that is convex toward an outside of the semiconductor substrate between the first surface and the sidewall surface.

3. The method of claim 1, wherein the first edge surface is an inclined plane between the first surface and the sidewall surface.

4. The method of claim 1, wherein the first edge width is larger than 0 μm and equal to or smaller than 200 μm.

5. The method of claim 1, wherein the first edge height is larger than 0 μm and smaller than 200 μm.

6. The method of claim 1,
wherein the ring-shaped edge region further includes a second edge surface between the second surface and the sidewall surface, and
the second edge surface is parallel to the second surface and perpendicular to the sidewall surface.

7. The method of claim 1,
wherein the ring-shaped edge region further includes a second edge surface between the second surface and the sidewall surface, and
the second edge surface is a second chamfered surface extending from the second surface to the sidewall surface.

8. The method of claim 7,
wherein a second edge width of the second edge surface in the second direction is equal to or larger than the first edge width, and
a second edge height of the second edge surface in the first direction is equal to or larger than the first edge height.

9. The method of claim 8, wherein the second edge surface is a curved surface that is convex toward an outside of the semiconductor substrate between the second surface and the sidewall surface.

10. The method of claim 8, wherein the second edge surface is an inclined plane between the second surface and the sidewall surface.

11. The method of claim 7, wherein the first edge surface and the second edge surface are symmetric with respect to the virtual reference plane in the first direction.

12. The method of claim 7,
wherein the first edge surface and the second edge surface are asymmetrical relative to each other with respect to the virtual reference plane in the first direction,
a second edge width of the second edge surface in the second direction is larger than the first edge width, and
a second edge height of the second edge surface in the first direction is larger than the first edge height.

13. A semiconductor substrate having a first surface and a second surface opposite to each other in a first direction, the semiconductor substrate comprising a ring-shaped edge region,
wherein:
the first direction is perpendicular to the first surface and the second surface,
the ring-shaped edge region includes:
a sidewall surface extending in the first direction,
a first edge surface between the first surface and the sidewall surface, and
a second edge surface between the second surface and the sidewall surface, and
wherein the semiconductor substrate has a first thickness that is a distance between the first surface and the second surface in the first direction, and
wherein a first edge height of the first edge surface in the first direction is equal to or smaller than 65 % of the first thickness of the semiconductor substrate.

14. The semiconductor substrate of claim 13, wherein the second edge surface is parallel to the second surface and perpendicular to the sidewall surface.

15. The semiconductor substrate of claim 13, wherein the second edge surface is a chamfered surface extending from the second surface to the sidewall surface.

16. The semiconductor substrate of claim 15, wherein the second edge surface is a curved surface that is convex toward an outside of the semiconductor substrate between the second surface and the sidewall surface.

17. The semiconductor substrate of claim 15, wherein the second edge surface is an inclined plane between the second surface and the sidewall surface.

18. A stacked structure comprising:
a semiconductor substrate having an upper surface and a lower surface opposite to each other in a first direction and including a ring-shaped edge region; and
a plurality of semiconductor dies arranged on the upper surface of the semiconductor substrate,
wherein:
the first direction is perpendicular to the upper surface and the lower surface of the semiconductor substrate, and
the ring-shaped edge region includes:
a first edge surface adjacent to the upper surface of the semiconductor substrate,
a second edge surface adjacent to the lower surface of the semiconductor substrate, and
a sidewall surface extending in the first direction between the first edge surface and the second edge surface,
the first edge surface:
is a first chamfered surface extending from the upper surface of the semiconductor substrate to the sidewall surface, or
extends parallel to the upper surface of the semiconductor substrate and is perpendicular to the sidewall surface, and
the second edge surface extends parallel to the lower surface of the semiconductor substrate and is perpendicular to the sidewall surface.

19. The stacked structure of claim 18,
wherein a first edge height of the first edge surface in the first direction is smaller than a thickness of the semiconductor substrate in the first direction,
a first edge width of the first edge surface in a second direction is equal to or smaller than the thickness of the semiconductor substrate in the first direction, and
the second direction is parallel to the upper surface and the lower surface of the semiconductor substrate.

20. The stacked structure of claim 18, wherein the semiconductor substrate includes silicon carbide.
